(19) United States
(12) Patent Application Publication
(10) Pub. No.: US 2026/0020260 A1
(43) Pub. Date: Jan. 15, 2026

(54) METHOD OF MANUFACTURING SEMICONDUCTOR DEVICE INCLUDING SUPPORTING LAYER

(71) Applicant: NANYA TECHNOLOGY CORPORATION, NEW TAIPEI CITY (TW)

(72) Inventor: CHIA-CHE CHIANG, NEW TAIPEI CITY (TW)

(21) Appl. No.: 18/806,856

(22) Filed: Aug. 16, 2024

Related U.S. Application Data
(62) Division of application No. 18/770,906, filed on Jul. 12, 2024.

(51) Int. Cl. H10B 12/00

(52) U.S. Cl. CPC H10D 1/042; H10B 12/01; H10D 1/716

(57) ABSTRACT

A method for manufacturing a semiconductor device is provided. The method includes: providing a carrier; forming a lower supporting layer having an opening over the carrier; forming a first electrode within the opening, wherein the first electrode has an upper surface far away from the carrier; forming an upper supporting layer abutting the upper surface of the first electrode; and forming a capacitor dielectric and a second electrode on the first electrode.

### CROSS-REFERENCE TO RELATED APPLICATION

This application is a divisional application of U.S. Non-Provisional Application No. 18/770,906 filed July 12, 2024, which is incorporated herein by reference in its entirety.

### TECHNICAL FIELD

The present disclosure relates to a method for manufacturing the same, and more particularly, to a method for manufacturing a semiconductor device including supporting layers.

### DISCUSSION OF THE BACKGROUND

With integrated circuits (ICs) achieving regular increases in performance and miniaturization, advances in materials and design produce successive generations with smaller and more complex circuits.

A Dynamic Random Access Memory (DRAM) device is a type of random access memory that stores each bit of data in a separate capacitor within an integrated circuit. Typically, a DRAM is arranged in a square array of one capacitor and transistor per cell. A vertical transistor has been developed for the 4F² DRAM cell, where F stands for the photolithographic minimum feature width or critical dimension (CD). However, recently, DRAM manufacturers face the tremendous challenge of shrinking the memory cell area as the capacitor components spacing continues to shrink. For example, the leakage between capacitor components has become a critical issue.

This Discussion of the Background section is provided for background information only. The statements in this Discussion of the Background are not an admission that the subject matter disclosed herein constitutes prior art with respect to the present disclosure, and no part of this Discussion of the Background may be used as an admission that any part of this application constitutes prior art with respect to the present disclosure.

### SUMMARY

One aspect of the present disclosure provides a method of manufacturing a semiconductor device. The method includes: providing a carrier; forming a lower supporting layer having an opening over the carrier; forming a first electrode within the opening, wherein the first electrode has an upper surface far away from the carrier; forming an upper supporting layer abutting the upper surface of the first electrode; and forming a capacitor dielectric and a second electrode on the first electrode.

Another aspect of the present disclosure provides a method of manufacturing a semiconductor device. The method includes: providing a carrier; forming a lower supporting layer; forming an upper sacrifice layer over the lower supporting layer, wherein the lower supporting layer and the upper sacrifice layer defines an opening over the carrier; forming a first electrode within the opening, wherein the first electrode has an upper surface far away from the carrier and a lateral surface connected to the upper surface; removing a portion of the upper sacrifice layer to expose the lateral surface of the first electrode; forming a dielectric layer to cover the upper surface and the lateral surface of the first electrode; removing a first portion of the dielectric layer over the upper surface of the first electrode to form an upper supporting layer surrounding the lateral surface of the first electrode; removing the upper sacrifice layer; and forming a capacitor dielectric and a second electrode on the first electrode.

Another aspect of the present disclosure provides a method of manufacturing a semiconductor device. The method includes: providing a carrier; forming a lower supporting layer, an upper sacrifice layer, a middle supporting layer, and a lower sacrifice layer over the carrier; patterning the lower supporting layer, the upper sacrifice layer, the middle supporting layer, and the lower sacrifice layer to form an opening; forming a first electrode within the opening, wherein the first electrode has an upper surface far away from the carrier; and forming an upper supporting layer on the lower sacrifice layer and abutting the upper surface of the first electrode.

The embodiments of the present disclosure illustrate a method of manufacturing a semiconductor device. In this embodiment, the upper supporting layer and the cap layer for patterning the middle supporting layer are formed simultaneously or by the same step, whereas in a comparative example, the cap layer is formed after the upper supporting layer is patterned. Under this condition, the upper sacrifice layer may form a bow-shaped profile at a stage for patterning the upper supporting layer and the upper sacrifice layer, potentially causing a leakage due to the reduced distance between abutting electrodes. Therefore, the method of the present disclosure offers a solution to the issue of the conventional method.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

A more complete understanding of the present disclosure may be derived by referring to the detailed description and claims when considered in connection with the Figures, where like reference numbers refer to similar elements throughout the Figures, and:

FIG. 1 is a cross-sectional view of a semiconductor device, in accordance with some embodiments of the present disclosure.

FIG. 2 is a cross-sectional view of a semiconductor device, in accordance with some embodiments of the present disclosure.

FIG. 3 is a flowchart illustrating a method of manufacturing a semiconductor device, in accordance with some embodiments of the present disclosure.

FIG. 4A illustrates one or more stages of an exemplary method for manufacturing a semiconductor device according to some embodiments of the present disclosure.

FIG. 4B illustrates one or more stages of an exemplary method for manufacturing a semiconductor device according to some embodiments of the present disclosure.

FIG. 4C illustrates one or more stages of an exemplary method for manufacturing a semiconductor device according to some embodiments of the present disclosure.

FIG. 4D illustrates one or more stages of an exemplary method for manufacturing a semiconductor device according to some embodiments of the present disclosure.

FIG. 4E illustrates one or more stages of an exemplary method for manufacturing a semiconductor device according to some embodiments of the present disclosure.

FIG. 4F illustrates one or more stages of an exemplary method for manufacturing a semiconductor device according to some embodiments of the present disclosure.

FIG. 4G illustrates one or more stages of an exemplary method for manufacturing a semiconductor device according to some embodiments of the present disclosure.

FIG. 4H illustrates one or more stages of an exemplary method for manufacturing a semiconductor device according to some embodiments of the present disclosure.

FIG. 4I illustrates one or more stages of an exemplary method for manufacturing a semiconductor device according to some embodiments of the present disclosure.

FIG. 4J illustrates one or more stages of an exemplary method for manufacturing a semiconductor device according to some embodiments of the present disclosure.

FIG. 4K illustrates one or more stages of an exemplary method for manufacturing a semiconductor device according to some embodiments of the present disclosure.

FIG. 4L illustrates one or more stages of an exemplary method for manufacturing a semiconductor device according to some embodiments of the present disclosure.

FIG. 4M illustrates one or more stages of an exemplary method for manufacturing a semiconductor device according to some embodiments of the present disclosure.

### DETAILED DESCRIPTION

Embodiments, or examples, of the disclosure illustrated in the drawings are now described using specific language. It shall be understood that no limitation of the scope of the disclosure is hereby intended. Any alteration or modification of the described embodiments, and any further applications of principles described in this document, are to be considered as normally occurring to one of ordinary skill in the art to which the disclosure relates. Reference numerals may be repeated throughout the embodiments, but this does not necessarily mean that feature(s) of one embodiment apply to another embodiment, even if they share the same reference numeral.

It shall be understood that, although the terms first, second, third, etc., may be used herein to describe various elements, components, regions, layers or sections, these elements, components, regions, layers or sections are not limited by these terms. Rather, these terms are merely used to distinguish one element, component, region, layer or section from another region, layer or section. Thus, a first element, component, region, layer or section discussed below could be termed a second element, component, region, layer or section without departing from the teachings of the present inventive concept.

The terminology used herein is for the purpose of describing particular example embodiments only and is not intended to be limited to the present inventive concept. As used herein, the singular forms “a,” “an” and “the” are intended to include the plural forms as well, unless the context clearly indicates otherwise. It shall be further understood that the terms “comprises” and “comprising,” when used in this specification, point out the presence of stated features, integers, steps, operations, elements, or components, but do not preclude the presence or addition of one or more other features, integers, steps, operations, elements, components, or groups thereof.

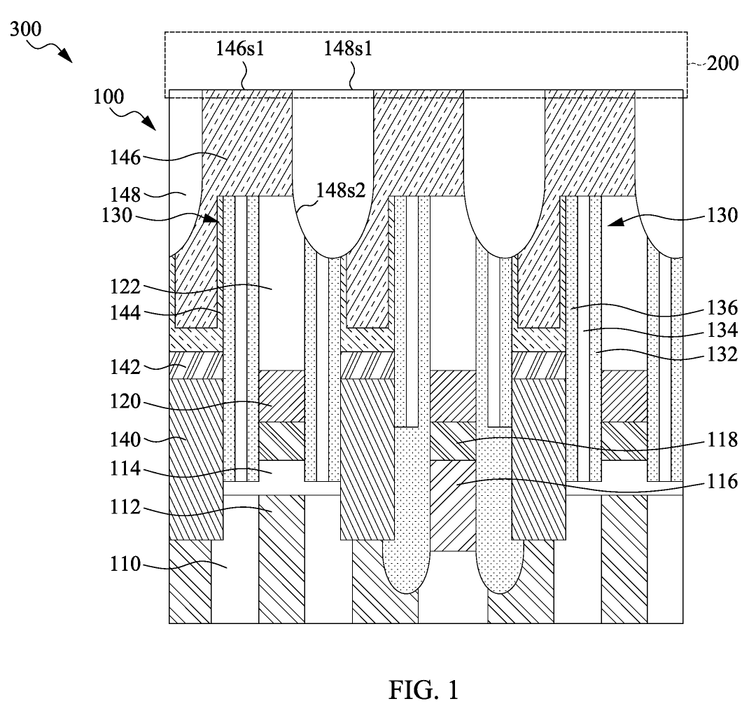

FIG. 1A is a cross-sectional view of a semiconductor device 300, in accordance with some embodiments of the present disclosure. In some embodiments, the semiconductor device 300 may include a cell region in which a memory device is formed. The memory device may include, for example, a dynamic random access memory (DRAM) device, a one-time programming (OTP) memory device, a static random access memory (SRAM) device, or other suitable memory devices. In some embodiments, a DRAM may include, for example, a transistor, a capacitor, and other components. During a read operation, a word line may be asserted, turning on the transistor. The enabled transistor allows the voltage across the capacitor to be read by a sense amplifier through a bit line. During a write operation, the data to be written may be provided on the bit line when the word line is asserted.

In some embodiments, the semiconductor device 300 may include a peripheral region (not shown) utilized to form a logic device (e.g., system-on-a-chip (SoC), central processing unit (CPU), graphics processing unit (GPU), application processor (AP), microcontroller, etc.), a radio frequency (RF) device, a sensor device, a micro-electro-mechanical-system (MEMS) device, a signal processing device (e.g., digital signal processing (DSP) device)), a front-end device (e.g., analog front-end (AFE) devices) or other devices.

The semiconductor device 300 may include a carrier 100 and a device disposed over the carrier 100. The carrier 100 may include a switch (e.g., transistor) configured to turn on or turn off a capacitor(s) within the device 200.

The carrier 100 may include a substrate 110. The substrate 110 may be a semiconductor substrate, such as a bulk semiconductor, a semiconductor-on-insulator (SOI) substrate, or the like. The substrate 110 may include an elementary semiconductor including silicon or germanium in a single crystal form, a polycrystalline form, or an amorphous form; a compound semiconductor material including at least one of silicon carbide, gallium arsenide, gallium phosphide, indium phosphide, indium arsenide, and indium antimonide; an alloy semiconductor material including at least one of SiGe, GaAsP, AlInAs, AlGaAs, GaInAs, GaInP, and GaInAsP; any other suitable materials; or a combination thereof. In some embodiments, the alloy semiconductor substrate may be a SiGe alloy with a gradient Ge feature in which the Si and Ge composition changes from one ratio at one location to another ratio at another location of the gradient SiGe feature. In another embodiment, the SiGe alloy is formed over a silicon substrate. In some embodiments, a SiGe alloy may be mechanically strained by another material in contact with the SiGe alloy. In some embodiments, the substrate 110 may have a multilayered structure, or the substrate 110 may include a multilayered compound semiconductor structure.

In some embodiments, the carrier 100 may include a plurality of active areas. The active area may function as, for example, a channel for electrical connection.

In some embodiments, the carrier 100 may include isolation structures 112. In some embodiments, the plurality of active areas may be separated by the isolation structures 112. In some embodiments, the isolation structures 112 may be embedded in the substrate 110. In some embodiments, the isolation structures 112 may include, for example, silicon oxide (SiO₂), silicon nitride (Si₃N₄), silicon oxynitride (N₂OSi₂), silicon nitride oxide (N₂OSi₂), or other suitable materials. In some embodiments, a portion of the substrate 110 may be removed to form trenches, and a dielectric material(s) is filled into the trenches to form the isolation structures 112.

In some embodiments, the carrier 100 may include a dielectric layer 114. The dielectric layer 114 may be disposed on the substrate 110. In some embodiments, the dielectric layer 114 may cover a portion of the isolation structures 112. In some embodiments, the dielectric layer 114 may include, for example, silicon oxide (SiO₂), silicon nitride (Si₃N₄), silicon oxynitride (N₂OSi₂), silicon nitride oxide (N₂OSi₂), a high-k material or combinations thereof. Examples of the high-k material include a dielectric material having a dielectric constant exceeding that of silicon dioxide (SiO₂), or a dielectric material having a dielectric constant higher than about 3.9. In some embodiments, the dielectric layer 114 may include at least one metallic element, such as hafnium oxide (HfO₂), silicon doped hafnium oxide (HSO), lanthanum oxide (La₂O₃), lanthanum aluminum oxide (LaAlO₃), zirconium orthosilicate (ZrSiO₄), aluminum oxide (Al₂O₃) or combinations thereof.

In some embodiments, the carrier 100 may include a bit line contact 116. In some embodiments, the bit line contact 116 may be disposed on the active area of the 100. The bit line contact 116 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), alloys combinations thereof or any metallic material with suitable resistance and gap-fill capability.

In some embodiments, the carrier 100 may include bit line stacks 118. In some embodiments, the bit line stack 118 may include a multilayered structure. In some embodiments, a portion of the bit line stacks 118 may be disposed on the bit line contact 116. A portion of the bit line stacks 118 may be spaced apart from the substrate 110 by the dielectric layer 114. In some embodiments, a portion of the bit line stacks 118 may be in contact with the bit line contact 116. In some embodiments, a portion of the bit line stacks 118 may be electrically connected to the bit line contact 116. In some embodiments, a portion of the bit line stacks 118 may be disposed on the dielectric layer 114. In some embodiments, a portion of the bit line stacks 118 may be in contact with the dielectric layer 114. The bit line stack 118 may include titanium (Ti), tantalum (Ta), titanium nitride (TiN), copper (Cu), tantalum nitride (TaN), manganese nitride (MnN) or a combination thereof.

In some embodiments, the carrier 100 may include bit lines 120. In some embodiments, each of the bit lines 120 may be disposed on the bit line stack 118. In some embodiments, a portion of the bit lines 120 may be disposed on the bit line contact 116. In some embodiments, a portion of the bit lines 120 may be electrically connected to the bit line contact 116. In some embodiments, a portion of the bit lines 120 may be disposed on the dielectric layer 114. The bit line 120 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), alloys thereof, or combinations thereof.

In some embodiments, the carrier 100 may include dielectric layers 122. In some embodiments, each of the dielectric layers 122 may be disposed on the bit line 120. In some embodiments, the dielectric layer 122 may include, for example, silicon oxide, silicon nitride, silicon oxynitride, silicon nitride oxide, a high-k material or combinations thereof.

In some embodiments, the carrier 100 may include isolation spacers 130. The isolation spacer 130 may be disposed on a side of the bit line 120. It should be noted that the isolation spacer 130 may have a circular profile, an elliptical profile, or the like which surrounds the bit line 120 from a top view.

In some embodiments, the isolation spacer 130 may have a dielectric layer 132, an air gap 134, and a dielectric layer 136. In some embodiments, the dielectric layer 132 may be formed on the sidewalls of the bit line contact 116, the bit line stack 118, the bit line 120, and the dielectric layer 122. In some embodiments, a portion of the dielectric layer 132 may be embedded in the substrate 110. In some embodiments, the dielectric layer 132 may include, for example, silicon oxide, silicon nitride, silicon oxynitride, silicon nitride oxide, a high-k material or combinations thereof.

In some embodiments, the air gap 134 may be spaced apart from the bit line 120 by the dielectric layer 132. The air gap 134 may be disposed between the dielectric layers 132 and 136. In some embodiments, the air gap 134 may be replaced by a dielectric material(s) with a suitable dielectric constant.

In some embodiments, the dielectric layer 136 may be spaced apart from the dielectric layer 132 by the air gap 134. In some embodiments, the dielectric layer 136 may include, for example, silicon oxide, silicon nitride, silicon oxynitride, silicon nitride oxide, a high-k material or combinations thereof.

In some embodiments, the carrier 100 may include a capacitor contact 140. In some embodiments, a portion of the capacitor contact 140 may be in contact with the substrate 110. In some embodiments, the capacitor contact 140 may be formed between two bit lines 120. In some embodiments, the capacitor contact 140 may be formed between the isolation spacer 130. The capacitor contact 140 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), alloys thereof, combinations thereof or any metallic material.

In some embodiments, the carrier 100 may include a conductive stack structure 142. The conductive stack structure 142 may include a multilayered structure. In some embodiments, the conductive stack structure 142 may be formed on a top surface of the capacitor contact 140. The conductive stack structure 142 may be disposed between the isolation spacers 130. In some embodiments, the conductive stack structure 142 may include metal silicide, such as, cobalt silicide (CoSi) or other suitable materials.

In some embodiments, the carrier 100 may include a liner 144. In some embodiments, the liner 144 may be formed on a top surface of the capacitor contact 140. In some embodiments, the liner 144 may be disposed on the sidewalls of the isolation spacer 130. In some embodiments, the liner 144 may include metal nitride, such as titanium nitride (TiN), aluminum nitride (AlN), hafnium nitride (HfN), lanthanum nitride (LaN), scandium nitride (ScN), or other suitable materials.

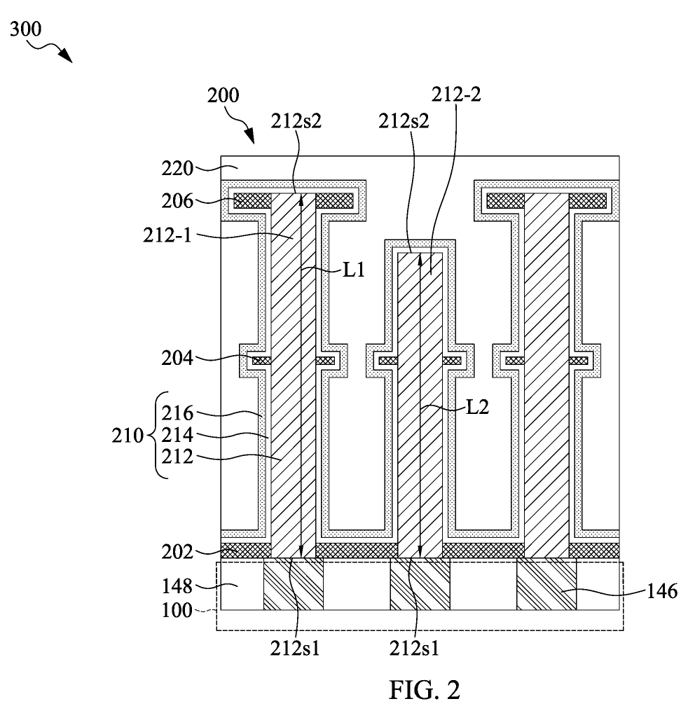

In some embodiments, the carrier 100 may include pads 146 (or landing pads). Each of the pads 146 may be configured to electrically connect a capacitor structure (shown in FIG. 2). In some embodiments, the pad 146 may be formed on the liner 144. In some embodiments, the pad 146 may be formed between the isolation spacers 130. In some embodiments, the pad 146 may cover a top surface the isolation spacer 130. In some embodiments, the pad 146 may cover a top surface of the dielectric layer 132. In some embodiments, the pad 146 may cover a top surface of the dielectric layer 136. In some embodiments, the air gap 134 may be covered by the pad 146. In some embodiments, a portion of the pad 146 may be surrounded by the liner 144. In some embodiments, the pad 146 may cover a top surface of the dielectric layer 122. In some embodiments, the pad 146 may include an upper portion over the dielectric layer 122 and a lower portion between adjacent dielectric layers 122. In some embodiments, the pad 146 may include metal, such as tungsten (W), copper (Cu), ruthenium (Ru), iridium (Ir), nickel (Ni), osmium (Os), rhodium (Rh), aluminum (Al), molybdenum (Mo), cobalt (Co), silver (Ag), gold (Au), alloys thereof, or combinations thereof.

In some embodiments, the carrier 100 may include a passivation layer 148. In some embodiments, the air gap 134 may be covered by the passivation layer 148. In some embodiments, the passivation layer 148 may be spaced apart from the isolation spacer 130 by the pad 146. The passivation layer 148 may have a surface 148s1 and a surface 148s2. The surface 148s1 (or a top surface) may face away from the carrier 100. The surface 148s2 (or a lateral surface) may cover or in contact with the dielectric layer 122. In some embodiments, the passivation layer 148 may include silicon nitride, silicon oxide, or other suitable materials. In some embodiments, the surface 148s1 of the passivation layer 148 may be substantially aligned or coplanar with a surface 146s1 (or a top surface) of the pad 146.

Although not shown in FIG. 1, the carrier 100 may include more components, such as word lines and/or other conductive and non-conductive layers, based on the design requirements. For example, the word line may be formed by a trench gate technique and formed within the substrate 110.

In some embodiments, the semiconductor device 300 may include a device 200. The device 200 may be disposed on or over the pad 146. The device 200 may include a capacitor component electrically connected to the pad 146. The transistors shown in FIG. 1 may be configured to switch on or off the capacitor component within the device 200.

FIG. 2 illustrates the device 200 in detail according to some embodiments of the present disclosure.

The device 200 may be disposed over the carrier 100 to cover the pad 146. In some embodiments, the device 200 may include a supporting layer 202, a supporting layer 204, and a supporting layer 206 which are located at different elevations and configured to support a capacitor component 210.

In some embodiments, the supporting layer 202 (or a lower supporting layer) may be disposed on or over the passivation layer 148. In some embodiments, the supporting layer 202 may cover a portion of the pad 146. In some embodiments, the supporting layer 202 may be in contact with the pad 146. In some embodiments, the supporting layer 202 may be configured to support the capacitor component 210. The supporting layer 202 may be utilized to define the patterns of the capacitor component 210. In some embodiments, the supporting layer 202 may include silicon nitride, silicon oxide, silicon oxynitride, silicon nitride oxide, or other suitable materials.

In some embodiments, the supporting layer 204 (or a middle supporting layer) may be disposed on or over the supporting layer 202. In some embodiments, the supporting layer 204 may be spaced apart from the supporting layer 202. In some embodiments, the supporting layer 204 may be configured to support the capacitor component 210. The supporting layer 204 may be utilized to define the patterns of the capacitor component 210. In some embodiments, the supporting layer 204 may include silicon nitride, silicon oxide, silicon oxynitride, silicon nitride oxide, or other suitable materials.

In some embodiments, the supporting layer 206 (or an upper supporting layer) may be disposed on or over the supporting layer 204. In some embodiments, the supporting layer 206 may be spaced apart from the supporting layer 204. In some embodiments, the supporting layer 206 may be configured to support the capacitor component 210. The supporting layer 206 may be utilized to define the patterns of the capacitor component 210. In some embodiments, the supporting layer 206 may include silicon nitride, silicon oxide, silicon oxynitride, silicon nitride oxide, or other suitable materials.

The capacitor component 210 may be disposed on or over the carrier 100. In some embodiments, the capacitor component 210 may be electrically connected to the pad 146. In some embodiments, the capacitor component 210 may be supported by and in contact with the supporting layer 202, supporting layer 204, and supporting layer 206. In some embodiments, the capacitor component 210 may include a lower electrode 212, a capacitor dielectric 214, and an upper electrode 216.

In some embodiments, the lower electrode 212 (or first electrode) may be disposed on the carrier 100. In some embodiments, the lower electrode 212 may be disposed on and electrically connected to the pad 146. In some embodiments, the lower electrode 212 may be disposed within the opening defined by the supporting layer 202, supporting layer 204, and supporting layer 206. In some embodiments, the lower electrode 212 may be disposed on or in contact with the lateral surface of the supporting layer 202. In some embodiments, the lower electrode 212 may be disposed on or in contact with the lateral surface of the supporting layer 204. In some embodiments, the lower electrode 212 may be disposed on or in contact with the lateral surface of the supporting layer 206. The lower electrode 212 may include conductive material(s), conductive metal nitride (e.g., titanium nitride, tantalum nitride, tungsten nitride, or the like), metal (e.g., copper, tungsten, ruthenium, iridium, nickel, osmium, rhodium, aluminum, molybdenum, cobalt, or the like), and conductive metal oxide (e.g., iridium oxide or the like).

The lower electrode 212 may have a surface 210s1 (or a lower surface) abutting the carrier 100 and a surface 210s2 (or an upper surface) opposite to the surface 210s1. In some embodiments, the thickness L1 (or length or depth) of the lower electrode 212-1 may be different from the thickness L2 (or length or depth) of the lower electrode 212-2.

The capacitor dielectric 214 may be conformally disposed on the lower electrode 212. In some embodiments, the capacitor dielectric 214 may be disposed on or in contact with the upper surface of the supporting layer 202. In some embodiments, the capacitor dielectric 214 may be disposed on or in contact with the upper surfaces of the supporting layer 204 and supporting layer 206. In some embodiments, the capacitor dielectric 214 may be disposed on or in contact with the lower surfaces of the supporting layer 204 and supporting layer 206. In some embodiments, the capacitor dielectric 214 may be disposed on or in contact with the lateral surfaces of the supporting layer 204 and supporting layer 206. The capacitor dielectric 214 may include silicon oxide, tungsten oxide, copper oxide, aluminum oxide, hafnium oxide, or the like.

In some embodiments, the upper electrode 216 (or second electrode) may be disposed on the capacitor dielectric 214. The upper electrode 216 may be spaced apart from the lower electrode 212 by the capacitor dielectric 214. The upper electrode 216 may include conductive material(s), conductive metal nitride (e.g., titanium nitride, tantalum nitride, tungsten nitride, or the like), metal (e.g., copper, tungsten, ruthenium, iridium, nickel, osmium, rhodium, aluminum, molybdenum, cobalt, or the like), and conductive metal oxide (e.g., iridium oxide or the like). In some embodiments, each of the supporting layer 202, supporting layer 204, and supporting layer 206 may define a ring profile, from a top view, to accommodate the capacitor component 210.

In some embodiments, the device 200 further includes a grounding electrode 220. In some embodiments, the grounding electrode 220 may be electrically connected to ground. In some embodiments, the grounding electrode 220 may be electrically connected to the capacitor component 210. In some embodiments, the grounding electrode 220 may be electrically connected to and in contact with the upper electrode 216. In some embodiments, the grounding electrode 220 may include doped polysilicon or other suitable materials.

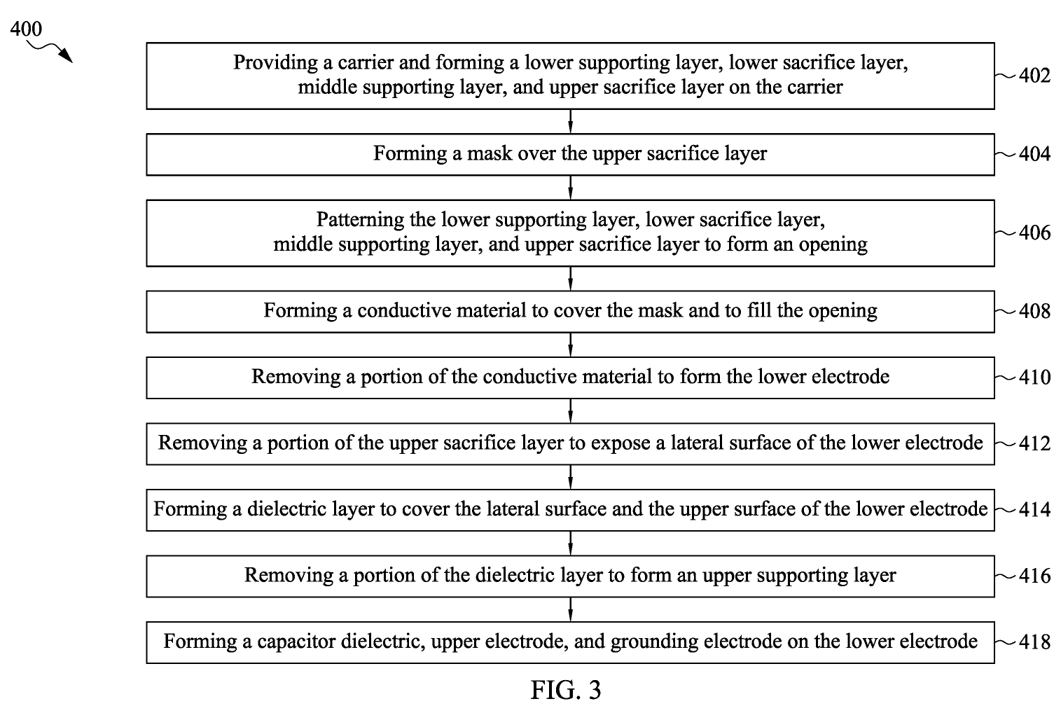

FIG. 3 is a flowchart illustrating a method 400 of manufacturing a semiconductor device, in accordance with some embodiments of the present disclosure.

The method 400 may begin with an operation 402 in which a carrier is provided. The carrier may include pads (or landing pads). A lower supporting layer, a lower sacrifice layer, a middle supporting layer, and an upper sacrifice layer are formed on the carrier.

The method 400 may continue with an operation 404 in which a mask which is patterned is formed on or over the upper sacrifice layer.

The method 400 may continue with an operation 406 in which the lower supporting layer, the lower sacrifice layer, the middle supporting layer, and the upper sacrifice layer are patterned to define an opening. The pads may be exposed by the opening.

The method 400 may continue with an operation 408 in which a conductive material is formed to cover the upper surface of the mask and to fill the openings.

The method 400 may continue with an operation 410 in which a portion of the conductive material is removed to form the lower electrode. The mask is removed. The upper surface of the lower electrode is substantially aligned with the upper surface of the upper sacrifice layer.

The method 400 may continue with an operation 412 in which a portion of the upper sacrifice layer is removed to expose a lateral surface of the lower electrode. The lower electrode protrudes from the upper surface of the upper sacrifice layer.

The method 400 may continue with an operation 414 in which a dielectric layer is formed to cover the lateral surface and the upper surface of the lower electrode and the upper surface of the upper sacrifice layer.

The method 400 may continue with an operation 416 in which the lower sacrifice layer, the upper sacrifice layer, a portion of the dielectric layer, and a portion of the middle supporting layer are removed. An upper surface is formed abutting the upper surface of the lower electrode.

The method 400 may continue with an operation 418 in which a capacitor dielectric and an upper capacitor electrode are formed on the lower capacitor electrode to define a capacitor component. A grounding electrode is formed on the capacitor component. As a result, a semiconductor device may be produced.

The method 400 is merely an example, and is not intended to limit the present disclosure beyond what is explicitly recited in the claims. Additional operations can be provided before, during, or after each operations of the method 400, and some operations described can be replaced, eliminated, or reordered for additional embodiments of the method. In some embodiments, the method 400 can include further operations not depicted in FIG. 3. In some embodiments, the method 400 can include one or more operations depicted in FIG. 3.

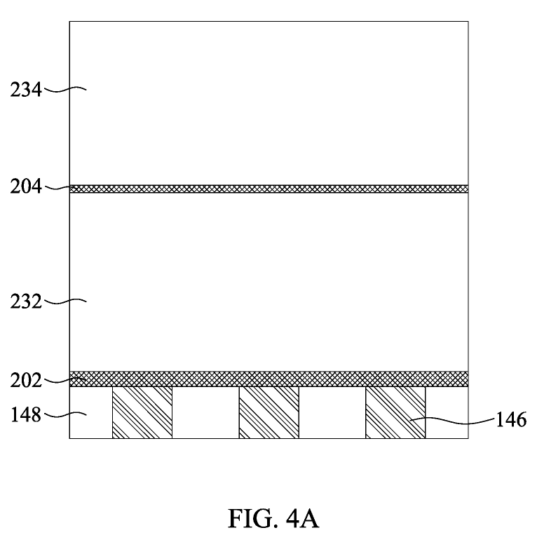

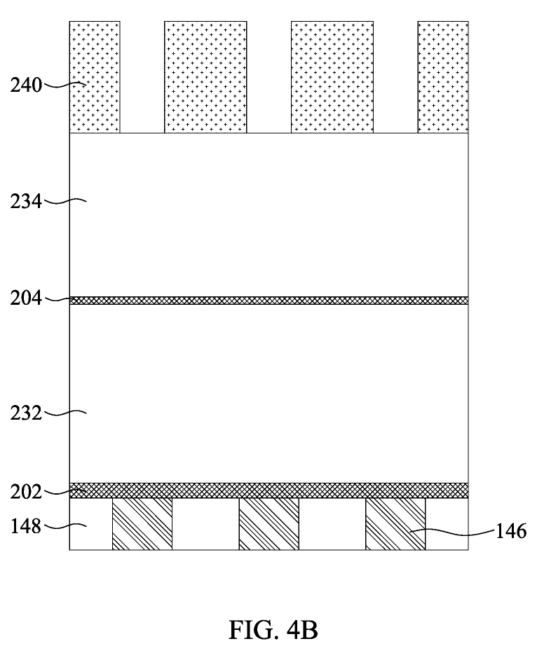

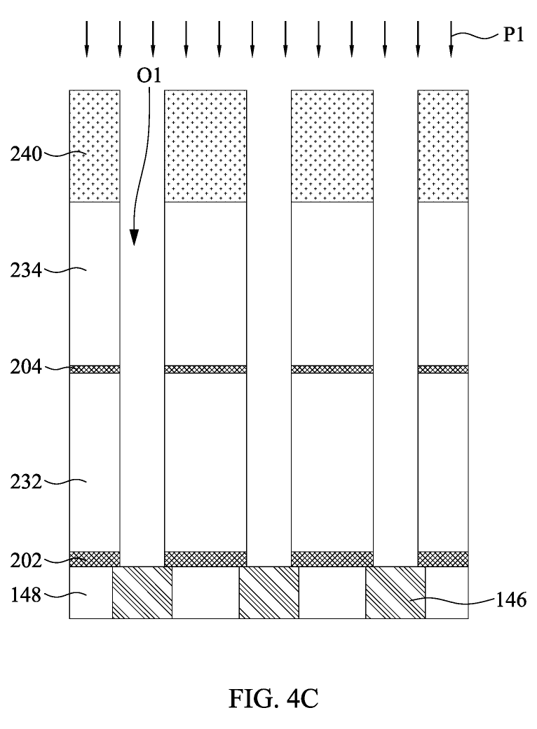

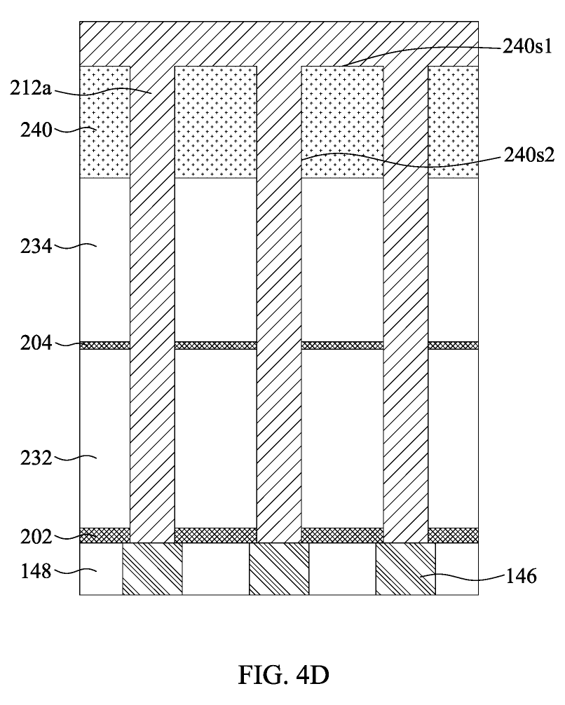

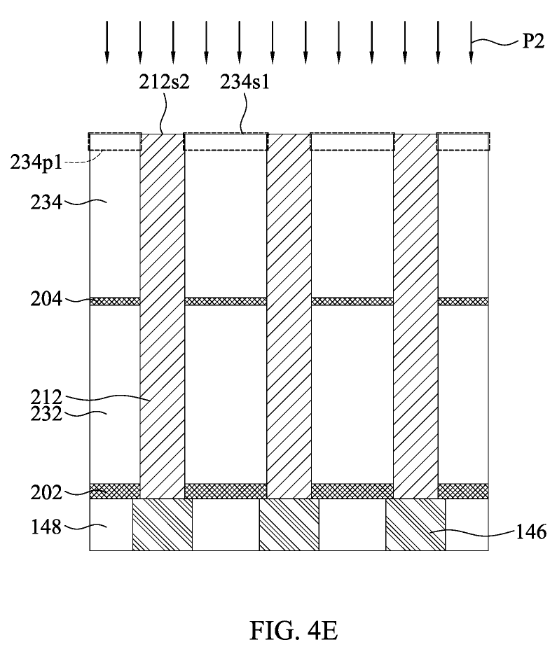

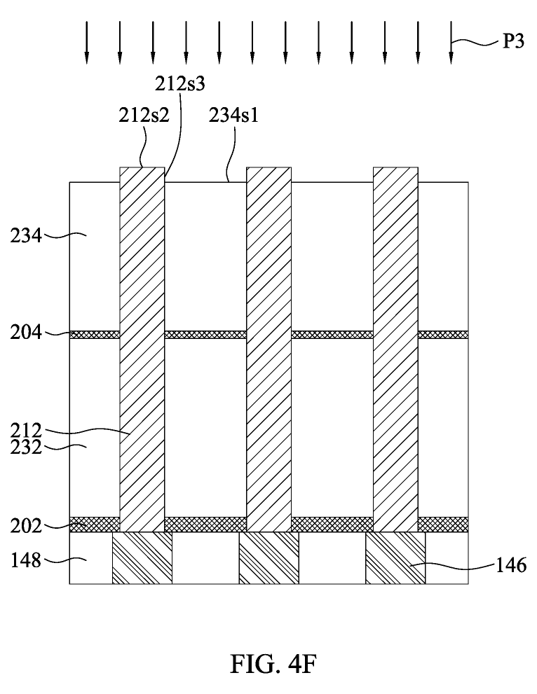

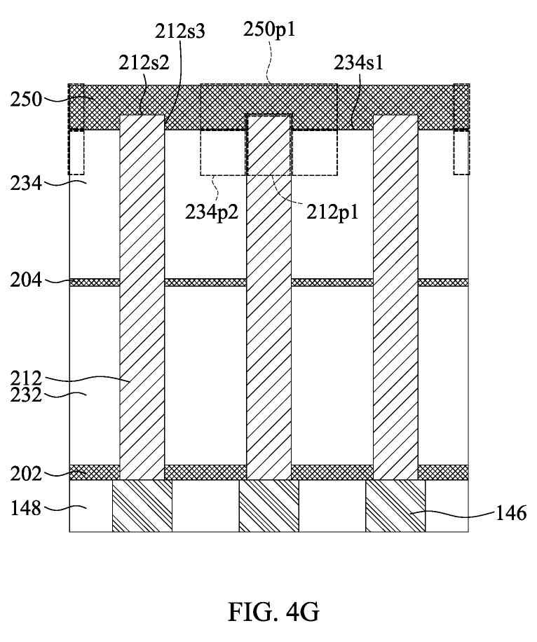

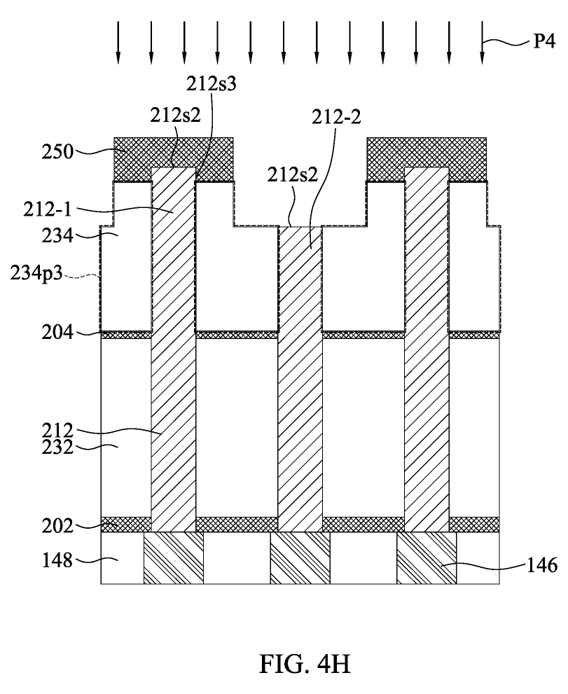

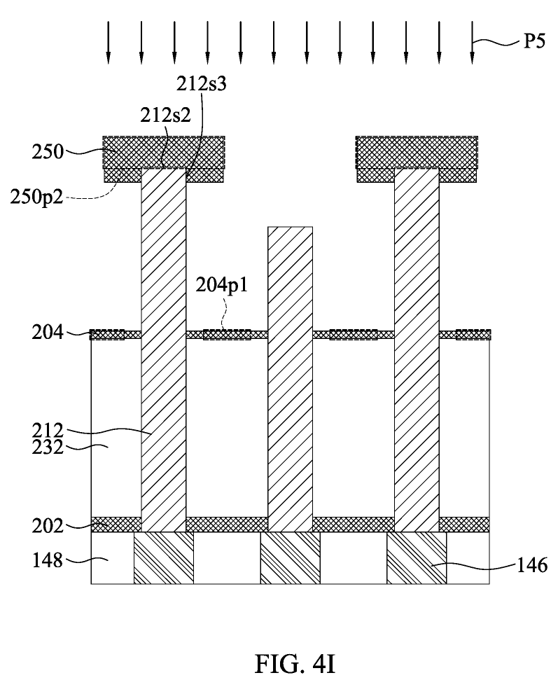

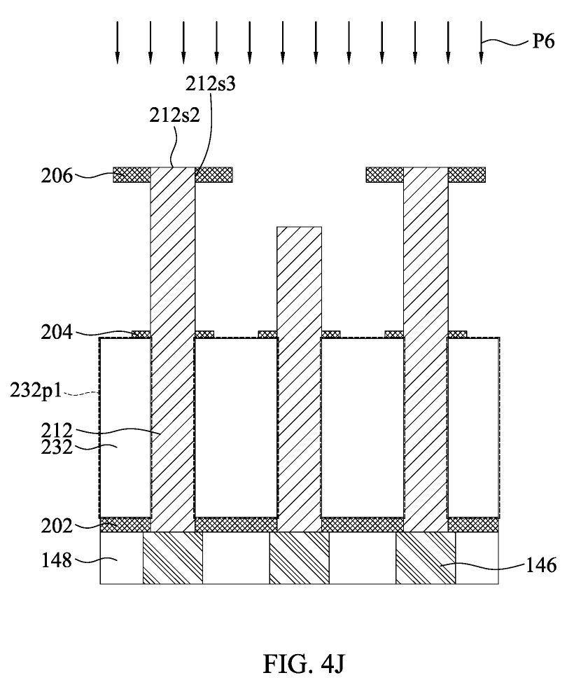

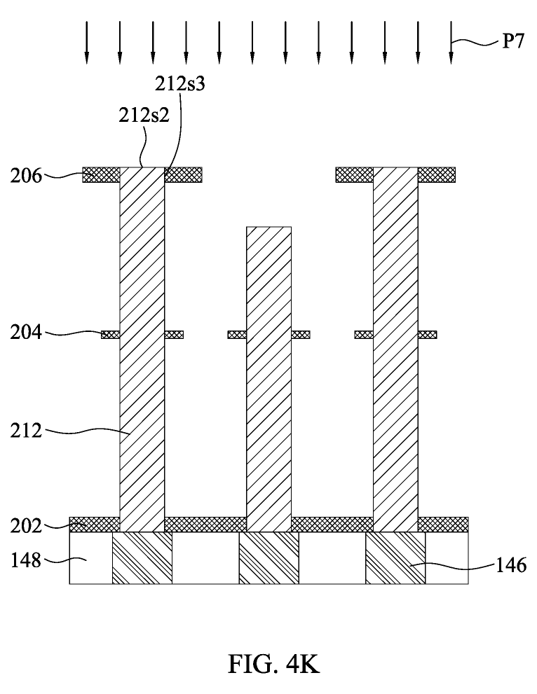

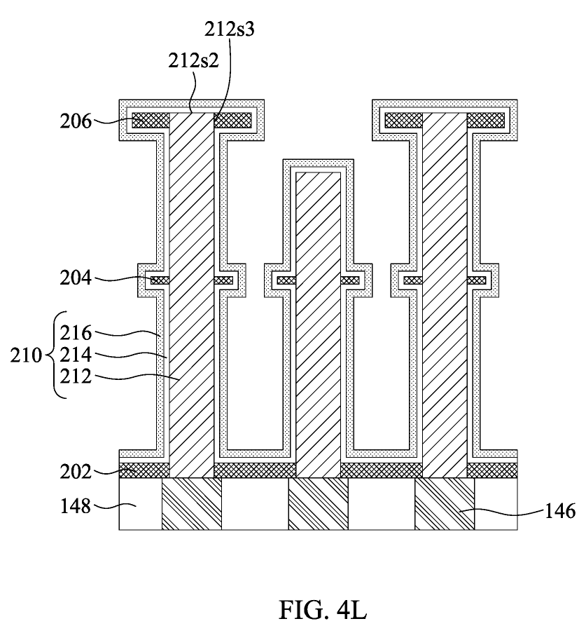

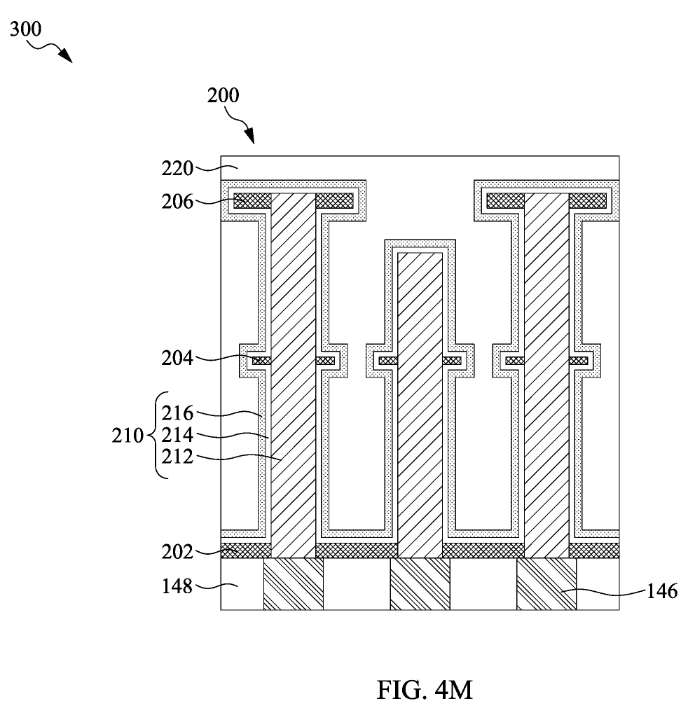

FIGS. 4A to FIG. 4M illustrates one or more stages of an exemplary method for manufacturing a semiconductor device according to some embodiments of the present disclosure.

Referring to FIG. 4A, the carrier 100 may be provided. The carrier 100 may include the pads 146 and the passivation layer 148 surrounding the pads 146. In some embodiments, the supporting layer 202 may be formed on or over the carrier 100. In some embodiments, the supporting layer 202 may be formed by, for example, chemical vapor deposition (CVD), atomic layer deposition (ALD), physical vapor deposition (PVD), low-pressure chemical vapor deposition (LPCVD), flowable chemical vapor deposition (FCVD), or other suitable process.

A sacrifice layer 232 (or a lower sacrifice layer) may be formed on or over the supporting layer 202. The sacrifice layer 232 may be removed in subsequent processes. In some embodiments, the material of the sacrifice layer 232 may be different from that of the supporting layer 202. In some embodiments, the sacrifice layer 232 may include silicon oxide, silicon nitride, silicon oxynitride, silicon nitride oxide, or other suitable materials. In some embodiments, the sacrifice layer 232 may be formed by, for example, chemical vapor deposition, atomic layer deposition, physical vapor deposition, low-pressure chemical vapor deposition, flowable chemical vapor deposition, or other suitable process.

The supporting layer 204 may be formed on or over the upper surface of the sacrifice layer 232. In some embodiments, the material of the supporting layer 204 may be different form that of the sacrifice layer 232. In some embodiments, the supporting layer 204 may be formed by, for example, chemical vapor deposition, atomic layer deposition, physical vapor deposition, low-pressure chemical vapor deposition, flowable chemical vapor deposition, or other suitable process. In some embodiments, the thickness of the supporting layer 204 may be less than that of the supporting layer 202.

A sacrifice layer 234 (or an upper sacrifice layer) may be formed on or over the supporting layer 204. The sacrifice layer 234 may be removed in subsequent processes. In some embodiments, the material of the sacrifice layer 234 may be different from that of the supporting layer 204. The material of the sacrifice layer 234 may be the same as that of the sacrifice layer 232. In some embodiments, the sacrifice layer 234 may include silicon oxide, silicon nitride, silicon oxynitride, silicon nitride oxide, or other suitable materials. In some embodiments, the sacrifice layer 234 may be formed by, for example, chemical vapor deposition, atomic layer deposition, physical vapor deposition, low-pressure chemical vapor deposition, flowable chemical vapor deposition, or other suitable process. FIG. 4A illustrates a stage corresponding to the operation 402 as shown in FIG. 3.

Referring to FIG. 4B, a mask 240 may be formed on or over the upper surface of the sacrifice layer 234. The mask 240 may be patterned to expose the sacrifice layer 234. In some embodiments, the mask 240 may be configured to define the pattern of openings for accommodating capacitor components. In some embodiments, the mask 240 may include one or more layers. The mask 240 may include, for example, polysilicon, silicon oxide, silicon oxynitride, or other suitable materials. The mask 240 may be formed by, for example, chemical vapor deposition, atomic layer deposition, physical vapor deposition, low-pressure chemical vapor deposition, flowable chemical vapor deposition, or other suitable process. The mask 240 may be patterned by a photolithography technique. FIG. 4B illustrates a stage corresponding to the operation 404 as shown in FIG. 3.

Referring to FIG. 4C, an etching technique P1 may be performed. The mask 240 may be patterned. The sacrifice layer 234 may be patterned. The supporting layer 204 may be patterned. The supporting layer 204 may be patterned. The sacrifice layer 232 may be patterned. The supporting layer 202 may be patterned. The openings O1 may be formed. In some embodiments, the openings may be defined by the sidewall of the mask 240, the sacrifice layer 234, the supporting layer 204, the sacrifice layer 232, and/or the supporting layer 202. The pad 146 may be exposed. The etching technique P1 may include dry etching, wet etching, or other suitable techniques. FIG. 4C illustrates a stage corresponding to the operation 406 as shown in FIG. 3.

Referring to FIG. 4D, a conductive material 212a (or a conductive layer) may be formed. In some embodiments, the conductive material 212a may formed within the openings O1. The conductive material 212a may cover a surface 240s1 (or an upper surface) of the mask 240. The conductive material 212a may be formed on a surface 240s2 (or a lateral surface) of the mask 240. The conductive material 212a may be formed by, for example, physical vapor deposition, chemical vapor deposition, atomic layer deposition, low-pressure chemical vapor deposition, flowable chemical vapor deposition, or other suitable process. FIG. 4D illustrates a stage corresponding to the operation 408 as shown in FIG. 3.

Referring to FIG. 4E, a removal technique P2 may be performed. In some embodiments, the removal technique P2 may include a chemical mechanical polishing technique (CMP), grinding technique, etching back technique, or other suitable techniques. A portion of the conductive material 212a may be removed. The mask 240 may be removed. The lower electrode 212 may be formed within the openings (e.g., openings O1) defined by the mask 240, the sacrifice layer 234, the supporting layer 204, the sacrifice layer 232, and/or the supporting layer 202. A surface 212s2 (or an upper surface) of the lower electrode 212 may be substantially aligned within a surface 234s1 (or an upper surface) of the sacrifice layer 234. FIG. 4E illustrates a stage corresponding to the operation 410 as shown in FIG. 3.

Referring to FIG. 4F, an etching technique P3 may be performed. A portion 234p1, as shown in FIG. 4E, of the sacrifice layer 234 may be removed. As a result, a surface 212s3 (or a lateral surface) of the lower electrode 212 may be exposed. In some embodiments, the lower electrode 212 may protrude from the surface 234s1 of the sacrifice layer 234 at this stage. In some embodiments, the surface 234s1 of the sacrifice layer 234 may be recessed from the lower electrode 212 at this stage. In some embodiments, the etchant used in the etching technique may include diluted hydrofluoric acid or other suitable etchants. In some embodiments, the etching technique P3 may include wet etching or other suitable techniques. In some embodiments, the distance between the surface 212s2 of the lower electrode 212 and the surface 234s1 of the sacrifice layer 234 may be configured to define the thickness of the upper supporting layer which will be formed in subsequent stages. FIG. 4F illustrates a stage corresponding to the operation 412 as shown in FIG. 3.

Referring to FIG. 4G, a dielectric layer 250 may be formed. In some embodiments, the dielectric layer 250 may cover the sacrifice layer 234. In some embodiments, the dielectric layer 250 may cover and in contact with the surface 212s2 of the lower electrode 212. In some embodiments, the dielectric layer 250 may cover and in contact with the surface 212s3 of the lower electrode 212. In some embodiments, the dielectric layer 250 may include silicon nitride, silicon oxide, silicon oxynitride, silicon nitride oxide, or other suitable materials. The dielectric layer 250 may be formed by, for example, chemical vapor deposition, atomic layer deposition, physical vapor deposition, low-pressure chemical vapor deposition, flowable chemical vapor deposition, or other suitable process.

In some embodiments, the dielectric layer 250 may include a first portion surrounding the surface 212s3 of the lower electrode 212 and a second portion over the surface 212s2 of the lower electrode 212. In some embodiments, the first portion may function as the upper supporting layer that defines the pattern of the capacitor component. In some embodiments, the second portion may function as a cap layer (or mask) that defines the pattern of the supporting layer 204 in subsequent stages. In this stage, the layer of the upper supporting layer (e.g., the supporting layer 206 shown in FIG. 2) and the layer of the cap layer are formed by one step (or stage). FIG. 4G illustrates a stage corresponding to the operation 414 as shown in FIG. 3.

Referring to FIG. 4H, an etching technique P4 may be performed. A portion 250p1, as shown in FIG. 4G, of the dielectric layer 250 may be removed. A portion 212p1, as shown in FIG. 4G, of the lower electrode 212 may be removed. A portion 234p2, as shown in FIG. 4G, of the sacrifice layer 234 may be removed. As a result, the lower electrode 212-1 and the lower electrode 212-2 may have different thicknesses or heights. The surface 212s2 of the lower electrode 212-2 may be exposed. The etching technique P4 may include dry etching, wet etching, or other suitable techniques.

Referring to FIG. 4I, an etching technique P5 may be performed. A portion 234p3, as shown in FIG. 4H, of the sacrifice layer 234 may be removed. The supporting layer 204 may be exposed. The etching technique P5 may include dry etching, wet etching, or other suitable techniques.

Referring to FIG. 4J, an etching technique P6 may be performed. A portion 250p2, as shown in FIG. 4I, of the dielectric layer 250 may be removed to form the supporting layer 206 covering and surrounding the surface 212s3 of the lower electrode 212. The surface 212s2 of the lower electrode 212 may be exposed. In some embodiments, the portion 250p2 of the dielectric layer 250 may function as a cap (or mask) which is configured to define the pattern of the supporting layer 204 in subsequent stages. A portion 204p1, as shown in FIG. 4I, of the supporting layer 204 may be removed. The sacrifice layer 232 may be exposed. The etching technique P6 may include dry etching, wet etching, or other suitable techniques. FIGS. 4H, 4I, and 4J illustrate a stage corresponding to the operation 416 as shown in FIG. 3.

Referring to FIG. 4K, an etching technique P7 may be performed. The sacrifice layer 232 (or the portion 232p1) may be removed. The supporting layer 202 may be exposed. The etching technique P7 may include dry etching, wet etching, or other suitable techniques.

Referring to FIG. 4L, the capacitor dielectric 214 may be formed on the lower electrode 212. The capacitor dielectric 214 may be formed on the 204. The upper electrode 216 may be formed on the capacitor dielectric 214. Each of the capacitor dielectric 214 and upper electrode 216 may be formed by, atomic layer deposition, chemical vapor deposition, physical vapor deposition, low-pressure chemical vapor deposition, flowable chemical vapor deposition, or other suitable process.

Referring to FIG. 4M, the grounding electrode 220 may be formed on the supporting layer 206. The grounding electrode 220 may be formed by, chemical vapor deposition, atomic layer deposition, physical vapor deposition, low-pressure chemical vapor deposition, flowable chemical vapor deposition, or other suitable process. As a result, the device 200 may be produced. FIGS. 4K, 4L, and 4M illustrate a stage corresponding to the operation 418 as shown in FIG. 3.

One aspect of the present disclosure provides a method of manufacturing a semiconductor device. The method includes: providing a carrier; forming a lower supporting layer having an opening over the carrier; forming a first electrode within the opening, wherein the first electrode has an upper surface far away from the carrier; forming an upper supporting layer abutting the upper surface of the first electrode; and forming a capacitor dielectric and a second electrode on the first electrode.

Another aspect of the present disclosure provides a method of manufacturing a semiconductor device. The method includes: providing a carrier; forming a lower supporting layer; forming an upper sacrifice layer over the lower supporting layer, wherein the lower supporting layer and the upper sacrifice layer defines an opening over the carrier; forming a first electrode within the opening, wherein the first electrode has an upper surface far away from the carrier and a lateral surface connected to the upper surface; removing a portion of the upper sacrifice layer to expose the lateral surface of the first electrode; forming a dielectric layer to cover the upper surface and the lateral surface of the first electrode; removing a first portion of the dielectric layer over the upper surface of the first electrode to form an upper supporting layer surrounding the lateral surface of the first electrode; removing the upper sacrifice layer; and forming a capacitor dielectric and a second electrode on the first electrode.

Another aspect of the present disclosure provides a method of manufacturing a semiconductor device. The method includes: providing a carrier; forming a lower supporting layer, an upper sacrifice layer, a middle supporting layer, and a lower sacrifice layer over the carrier; patterning the lower supporting layer, the upper sacrifice layer, the middle supporting layer, and the lower sacrifice layer to form an opening; forming a first electrode within the opening, wherein the first electrode has an upper surface far away from the carrier; and forming an upper supporting layer on the lower sacrifice layer and abutting the upper surface of the first electrode.

The embodiments of the present disclosure illustrate a method of manufacturing a semiconductor device. In this embodiment, the upper supporting layer and the cap layer for patterning the middle supporting layer are formed simultaneously or by the same step, whereas in a comparative example, the cap layer is formed after the upper supporting layer is patterned. Under this condition, the upper sacrifice layer may form a bow-shaped profile at a stage for patterning the upper supporting layer and the upper sacrifice layer, potentially causing a leakage due to the reduced distance between abutting electrodes. Therefore, the method of the present disclosure offers a solution to the issue of the conventional method.

Although the present disclosure and its advantages have been described in detail, it should be understood that various changes, substitutions and alterations may be made herein without departing from the spirit and scope of the disclosure as defined by the appended claims. For example, many of the processes discussed above may be implemented in different methodologies and replaced by other processes, or a combination thereof.

Moreover, the scope of the present application is not intended to be limited to the particular embodiments of the process, machine, manufacture, and composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, or steps.

What is claimed is:

1. A method of manufacturing a semiconductor device, comprising:
providing a carrier;
forming a lower supporting layer;
forming an upper sacrifice layer over the lower supporting layer, wherein the lower supporting layer and the upper sacrifice layer defines an opening over the carrier;
forming a first electrode within the opening, wherein the first electrode has an upper surface far away from the carrier and a lateral surface connected to the upper surface;
removing a portion of the upper sacrifice layer to expose the lateral surface of the first electrode;
forming a dielectric layer to cover the upper surface and the lateral surface of the first electrode;
removing a first portion of the dielectric layer over the upper surface of the first electrode to form an upper supporting layer surrounding the lateral surface of the first electrode;
removing the upper sacrifice layer; and
forming a capacitor dielectric and a second electrode on the first electrode.

2. The method of claim 1, further comprising:
removing a second portion of the dielectric layer and a second portion of the upper sacrifice layer before removing the first portion of the dielectric layer.

3. The method of claim 2, further comprising:
removing a portion of the first electrode, and the upper surface of the first electrode is substantially aligned with a surface of the upper sacrifice layer.

4. The method of claim 1, further comprising:
forming a lower sacrifice layer on the lower supporting layer;
forming a middle supporting layer on the lower sacrifice layer, wherein the upper sacrifice layer, the lower sacrifice layer, the lower supporting layer, and the middle supporting layer collectively define the opening; and
removing a portion of the middle supporting layer to expose the lower sacrifice layer.

5. The method of claim 4, wherein the first portion of the dielectric layer and the portion of the middle supporting layer are removed by the same removal technique.

6. The method of claim 1, further comprising:
forming a mask on the upper sacrifice layer; and
patterning the upper sacrifice layer and the lower supporting layer to form the opening.

7. The method of claim 6, wherein forming the first electrode comprises:
forming a conductive layer to fill the opening and cover an upper surface of the mask; and
patterning the conductive layer and removing the mask to form the first electrode.

8. The method of claim 7, wherein the portion of the conductive layer and the mask are removed by a chemical mechanical polishing technique.

9. The method of claim 7, wherein the upper surface of the first electrode is substantially aligned with an upper surface of the upper sacrifice layer after removing the portion of the conductive layer and the mask.

10. The method of claim 1, wherein the dielectric layer comprises nitride.
